(19) United States
(12) Patent Application Publication
(10) Pub. No.: US 2009/0109755 A1
(43) Pub. Date: Apr. 30, 2009

(54) Neighbor block refresh for non-volatile memory

(76) Inventors: Mori Edan, Netanya (IL); Assaf Shappir, Kiryat Ono (IL); Yair Sofer, Tel-Aviv (IL)

Correspondence Address: EMPK & Shiloh, LLP;c/o Landon IP, Inc., 1700 Diagonal Road, Suite 450, Alexandria, VA, 22314, US

(21) Appl. No.: 12/289,289

(22) Filed: Oct. 24, 2008

Related U.S. Application Data
(60) Provisional application No. 60/982,166, filed on Oct. 24, 2007.

(51) Int. Cl. G11C 16/04; G11C 16/06; G11C 7/00

(52) U.S. Cl. 365/185.11; 365/185.18; 365/185.25; 365/185.33; 365/222

(57) ABSTRACT

Two or more erase sectors (blocks) in a given physical sector of the array. When (after) erasing a target block, determining whether a neighbor block needs to be refreshed by checking a sub-population of Vt distributions at a given program level. Various timings and strategies for performing the refresh operation are disclosed. The effects of word line disturb (gate disturb) may thereby be reduced.

### CROSS-REFERENCE(S) TO RELATED APPLICATION(S)

This application claims priority from U.S. Provisional Patent Application No. 60/982,166 filed 24 Oct. 2007, which is hereby incorporated by reference in its entirety.

### TECHNICAL FIELD

The disclosure relates to techniques for operating semiconductor devices and, more particularly, to operating non-volatile memory (NVM), such as floating gate (FG) devices or charge-trapping devices such as nitride read only memory (NROM), or other microelectronic cells or structures.

### BACKGROUND

### The Field Effect Transistor

The transistor is a solid state semiconductor device which can be used for amplification, switching, voltage stabilization, signal modulation and many other functions. Generally, a transistor has three terminals, and a voltage applied to a specific one of the terminals controls current flowing between the other two terminals. One type of transistor is known as the field effect transistor (FET).

The terminals of a field effect transistor (FET) are commonly named source (S), gate (G) and drain (D). In the FET, a small amount of voltage is applied to the gate (G) in order to control current flowing between the source (S) and the drain (D). In FETs, the main current appears in a narrow conducting channel formed near (usually primarily under) the gate. This channel connects electrons from the source terminal to the drain terminal. The channel conductivity can be altered by varying the voltage applied to the gate terminal, enlarging or constricting the channel and thereby controlling the current flowing between the source and the drain.

FIG. 1 illustrates a FET 100 comprising a p-type substrate (or a p-well in the substrate), and two spaced-apart n-type diffusion areas—one of which will serve as the “source”, the other of which will serve as the “drain” of the transistor. The space between the two diffusion areas is the “channel”. A thin dielectric layer is disposed over the substrate in the neighborhood of the channel, and a “gate” structure is disposed over the dielectric layer atop the channel. (The dielectric under the gate is also commonly referred to as “gate oxide” or “gate dielectric”.) Electrical connections (not shown) may be made to the source, the drain, and the gate. The substrate may be grounded, or it may be biased at a desired voltage depending on applications.

Generally, when there is no voltage on the gate, there is no electrical conduction (connection) between the source and the drain. As voltage (of the correct polarity) is applied to the gate, there is a “field effect” in the channel between the source and the drain, and current can flow between the source and the drain, and can be controlled by the voltage applied to the gate. In this manner, a small signal (gate voltage) can control a relatively large signal (current flow between the source and the drain).

The FET 100 is exemplary of a MOSFET (metal oxide semiconductor FET) transistor. With the specified “n” and “p” types shown above, an “n-channel MOSFET” can be formed. With opposite polarities (swapping “p” for “n” in the diffusions, and “n” for “p” in the substrate or well), a p-channel FET can be formed. In CMOS (complementary metal oxide semiconductor), both n-channel and p-channel MOS transistors may be used, and are often paired with one another.

An integrated circuit (IC) device may comprise many millions of FETs on a single semiconductor “chip” (or “die”), measuring only a few centimeters on each side. Several IC chips may be formed simultaneously, on a single “wafer”, using conventional semiconductor fabrication processes including deposition, doping, photolithography, and etching. After all the chips are formed, they can be singulated from the wafer.

The Floating Gate Transistor

A floating gate transistor is generally a transistor structure, broadly based on the FET, as described hereinabove. As illustrated in FIG. 2, the floating gate transistor 200 has a source and a drain, but rather than having only one gate, it has two gates which are called control gate (CG) and floating gate (FG). It is this arrangement of control gate and floating gate which enables the floating gate transistor to function as a memory cell, as described hereinbelow.

The floating gate is disposed over tunnel oxide (comparable to the gate oxide of the FET). The floating gate is a conductor, the tunnel oxide is an insulator (dielectric material). Another layer of oxide (interpoly oxide, also a dielectric material) separates the floating gate from the control gate.

Since the floating gate is a conductor, and is surrounded by dielectric material, it can store a charge. Electrons can move around freely within the conductive material of the floating gate (which comports with the basic definition of a “conductor”).

Since the floating gate can store a charge, it can exert a field effect on the channel region between the source and the drain, in a manner similar to how a normal FET works, as described hereinabove. Mechanisms for storing charges on the floating gate structure, as well as removing charges from the floating gate, are described hereinbelow.

Generally, if a charge is stored on the floating gate, this represents a binary “1”. If no charge is stored on the floating gate, this represents a binary “0”. (These designations are arbitrary, and can be reversed so that the charged state represents binary “0” and the discharged state represents binary “1”.) That represents the programming “half” of how a floating gate memory cell operates. The other half is how to determine whether there is a charge stored on the floating gate—in other words, to “read” the memory cell. Generally, this is done by applying appropriate voltages to the source, drain and gate terminals, and determining how conductive the channel is. Some modes of operation for a floating gate memory cell are described hereinbelow.

Normally, the floating gate non-volatile memory (NVM) cell has only a single “charge-storing area”—namely, the conductive floating gate (FG) structure, and can therefore only store a single bit of information (binary “1” or binary “0”). More recently, using a technology referred to as “multi-level cell” (MLC), two or more bits can be stored in and read from the floating gate cell.

The NROM Memory Cell

Another type of memory cell, called a “nitride, read only memory” (NROM) cell, has a charge-storage structure which is different from that of the floating gate memory cell and which permits charges to be stored (or trapped) in two separate charge-storage areas. Generally, the two separate charge storage areas are located within a non-conductive layer disposed between the gate and the underlying substrate, such as a layer of nitride formed in an oxide-nitride-oxide (ONO) stack underneath the gate. The non-conductive layer acts as a charge-trapping medium. Generally, electrical charges will stay where they are put in the charge-trapping medium, rather than being free to move around as in the example of the conductive floating gate of the floating gate memory cell. A first bit of binary information (binary “1” or binary “0”) can be stored in a first portion (such as the left-hand side) of the charge-trapping medium, and a second bit of binary information (binary “1” or binary “0”) can be stored in a second portion (such as the right-hand side) of the charge-trapping medium. An alternative viewpoint is that different charge concentrations can be considered for each bit of storage. Using MLC technology, at least two bits can be stored in and read from each of the two portions (charge storage areas) of the charge-trapping medium (for a total of 4 bits), similarly 3 bits or more than 4 bits may be identified.

FIG. 3 illustrates a basic NROM memory cell, which may be viewed as a FET with an “ONO” structure inserted between the gate and the substrate. (One might say that the ONO structure is “substituted” for the gate oxide of the FET.)

The ONO structure is a stack (or “sandwich”) of bottom (lower) oxide 322, a charge-trapping material such as nitride 324, and a top (upper) oxide 326. The ONO structure may have an overall thickness of approximately 10-25 nm, such as 18 nm, as follows:
the bottom oxide layer 322 may be from 3 to 6 nm, for example 4 nm thick;
the middle nitride layer 324 may be from 3 to 8 nm, for example 4 nm thick; and
the top oxide layer 326 may be from 5 to 15 nm, for example 10 nm thick.

The NROM memory cell has two spaced apart diffusions 314 and 316 (which can function as source and drain, as discussed hereinbelow), and a channel region 320 defined in the substrate 312 between the two diffusion regions 314 and 316, and a gate 328 disposed above the ONO stack 321.

In FIG. 3, the diffusions are labeled “N+”. This means that they are regions in the substrate that have been doped with an electron donor material, such as phosphorous or arsenic. These diffusions are typically created in a larger region which p-type cell well (CW) is doped with boron (or indium or both). This is the normal “polarity” for an NVM cell employing electron injection (but which may also employ hole injection, such as for erase). With opposite polarity (boron or indium implants in a n-type cell well), the primary injection mechanism would be for holes, which is generally accepted to be not as effective as electron injection. One skilled in the art will recognize that the concepts disclosed herein can be applied to opposite polarity devices.

The charge-trapping material 324 is non-conductive, and therefore, although electrical charges can be stored in the charge-trapping material, they are not free to move around, they will generally stay where they are stored. Nitride is a suitable charge-trapping material. Charge trapping materials other than nitride may also be suitable for use as the charge-trapping medium. One such material is silicon dioxide with buried polysilicon islands. A layer (324) of silicon dioxide with polysilicon islands would be sandwiched between the two layers of oxide (322) and (326). Alternatively, the charge-trapping layer 324 may be constructed by implanting an impurity, such as arsenic, into a layer of silicon dioxide deposited on top of the bottom oxide 322.

The memory cell 300 is generally capable of storing at least two bits of data—at least one bit(s) in a first storage area of the nitride layer 324 represented by the dashed circle 323, and at least one bit(s) in a second storage area of the nitride layer 324 represented by the dashed circle 325. Thus, the NROM memory cell can be considered to comprise two “half cells”, each half cell capable of storing at least one bit(s). It should be understood that a half cell is not a physically separate structure from another half cell in the same memory cell. The term “half cell”, as it may be used herein, is used herein only to refer to the “left” or “right” bit storage area of the ONO stack (nitride layer). The storage areas 323, 325 may variously be referred to as “charge storage areas”, “charge-trapping areas”, and the like, throughout this document. (The two charge storage areas may also be referred to as the right and left “bits”.)

Each of the storage areas 323, 325 in the charge-trapping material 324 can exert a field effect on the channel region 320 between the source and the drain, in a manner similar to how a normal FET works, as described hereinabove (FIG. 2).

Generally, if a charge is stored in a given storage area of the charge-trapping material, this represents a binary “1”, and if no charge is stored in a given storage area of the charge-trapping material, this represents a binary “0”. (Again, these designations are arbitrary, and can be reversed so that the charged state represents binary “0” and the discharged state represents binary “1”.) That represents the programming “half” of how an NROM memory cell operates. The other half is how to determine whether there is a charge stored in a given storage area of the charge-trapping material—in other words, to “read” the memory cell. Generally, this is done by applying appropriate voltages to the diffusion regions (functioning as source and drain) and gate terminals, and determining how conductive the channel is.

Modes of Operation

Generally, the modes of operation for any NVM memory cell (either floating gate or NROM) include “program”, “erase” and “read”. Modes of operation for NROM are now discussed.

Program generally involves injecting electrons into the charge storage areas of the NROM cell, typically by a process known as channel hot electron (CHE) injection. Exemplary voltages to program (by CHE injection of electrons) the right bit (right bit storage area) of an NROM cell,
the left BL (acting as source, Vs) is set to 0 volts
the right BL (acting as drain, Vd) is set to +5 volts
the gate (Vg) is set to +8-10 volts
the substrate (Vb) is set to 0 volts
   and the bit storage area above the drain (right BL) becomes programmed. To program the left bit storage area, source and drain are reversed—the left bitline serves as the drain and the right bitline serves as the source.

Erase may involve injecting holes into the charge storage areas of the NROM cell, typically by a process known as hot hole injection (HHI). Generally, holes cancel out an electron (they are electrically opposite), on a one-to-one basis. For exemplary voltages to erase (by HHI injection of holes) the right bit of the NROM cell,
the left BL (acting as source, Vs) is set to float
the right BL (acting as drain, Vd) is set to +5 volts
the gate (Vg) is set to −7 volts
the substrate (Vb) is set to 0 volts
   and the bit storage area above the drain (right BL) becomes erased. To erase the left bit storage area, source and drain are reversed—the left bitline serves as the drain and the right bitline serves as the source.

Read may involve applying voltages to the terminals of the memory cell and, based on subsequent current flow, ascertaining the threshold voltage of the charge storage area within the cell. Generally, to read the right bit of the NROM cell, using “reverse read”,
the right BL (acting as source, Vs) is set to 0 volts
the left BL (acting as drain, Vd) is set to +2 volts
the gate (Vg) is set to +5 volts
the substrate (Vb) is set to 0 volts
   and the bit storage area above the source (right BL) can be read. To read the left bit storage area, source and drain are reversed—the left bitline serves as the source and the right bitline serves as the drain.

The following table summarizes the operating conditions discussed above, for an NROM cell, using representative (exemplary, approximate, illustrative, non-limiting) voltages.

| | Program | Erase | Read |
|---|---|---|---|
| Drain Voltage | +5 | +5 | +2 |
| Source Voltage | 0 | float | 0 |
| Gate Voltage | +10 | −7 | +5 |
| Substrate | 0 | 0 | 0 |
| Comment(s) | the bit above the | the bit above the | the bit above the |
| | drain becomes | drain becomes | source is read |
| | programmed | erased | |

The duration of the given operation (program, erase, read) may depend on the product specification and the process. For example: in a 4 bpc (bit per cell) product, programming may take a longer time, since an accurate programming is required. In general, “read” is the fastest operation that takes about 40-200 nanoseconds (ns), “programming” may take a few microseconds (μs), and “erase” can vary between tens of microseconds (μs) to a few milliseconds (ms).

It is worth noting that during the read operation, the bias conditions are quite similar to those used during programming, except for lower voltage magnitudes, and this can result in the injection of electrons from the drain to the charge-trapping area above the drain (or, in the case of a floating gate cell, into the floating gate), thereby affecting the programming of the selected memory cell.

Flash Memory and Memory Arrays

Memory arrays are well known, and comprise a plurality (many, including many millions) of memory cells organized (including physically arranged) in rows (usually represented in drawings as going across the page, horizontally, from left-to-right) and columns (usually represented in drawings as going up and down the page, from top-to-bottom).

FIG. 4A illustrates an exemplary, generic memory array. A plurality of bitlines, labeled BL(n−1) through BL(n+2), may extend in parallel with one another, vertically through the array (or a portion thereof). A plurality of wordlines, labeled WL(n−1) through WL(n+l), may extend in parallel with one another, horizontally through the array (or a portion thereof). The wordlines may be at a higher level than (deposited above) the bitlines.

A plurality of memory cells, labeled “a” through “i”, are disposed in the array, and may be connected to selected ones of the wordlines and bitlines passing thereby. The memory cells illustrated in FIG. 4A are representative of many millions of memory cells that may be resident on a single chip. The memory cells may, generally, be any type of memory cell such as such as floating gate (FG) devices or charge-trapping devices such as nitride read only memory (NROM) devices, or other microelectronic cells or structures. The gates of field-effect transistor (FET) based memory cells, such as FG or NROM, may be connected to the wordlines, and source/drain diffusions of the FET-based memory cells may be connected between adjacent bitlines, as shown.

Flash memory is a form of non-volatile memory (NVM) that can be electrically erased and reprogrammed. Flash memory architecture usually allows multiple memory locations to be erased or written in one programming operation. However, an erase operation is not mandatory for a Flash memory. A Flash memory can be designed to support only Program and Read operations. This kind of product is called OTP—“One Time Program”.

Generally, a Flash memory array may comprise a plurality (such as thousands) of Erase Sectors (an ESEC, a plurality of ESecs, or ESs). The ESecs may be arranged in a plurality of Erase Sector Groups (ESGs), Erase Groups (or EGs), Physical Pages, and Physical Sectors (PSecs, or PSs).

FIG. 4B illustrates an exemplary memory array having a plurality of Erase Sectors (Esecs), a plurality of Erase Sector Groups (ESGs), a plurality of Physical Pages, and a plurality of Physical Sectors (PSecs).

An Erase Sector (Esec) may also be referred to as a “block”. A Physical Page may be also be referred to as a “slice”.

Generally, all of the Erase Sectors (ESecs) in a Flash memory array are the same as one another, and there are usually a binary number of ESecs in each Erase Sector Group (ESG), a binary number of Erase Sector Groups (ESGs) in a Physical Page, and a binary number of ESGs in a Physical Sector (PSec).

In Flash memory, when an erase command is applied, all of the pages in an ESec will be erased. In FIG. 4B, each of the little rectangular blocks represents an Erase Sector (ESec) and, as mentioned above, typically there are thousands (or more) of Erase Sectors (Esecs) in a Flash memory array.

An Erase Sector Group (ESG) may comprise a number (such as 32) of wordlines, generally extending horizontally across the memory array. Or, another way of looking at it, an Erase Sector Group (ESG) may comprise a number of Erase Sectors (ESec) extending horizontally, next to one another, and sharing wordlines, across the memory array. See the dashed line box (and legend “one ESG”) in FIG. 4B.

Within a given Erase Sector (ESec), each wordline may be divided into a number (such as 4) of segments, which may be referred to as “pages”. A single wordline (WL) of a single given ESec may thus comprise several pages. Or, sometimes the term “page” may be used to refer to the aggregate of comparable (such as the first, second, third . . . or eighth) segments from a few different wordlines in the ESec, rather than a segment of only one wordline in the ESec.

A number (such as tens of, such as 32) of Erase Sector Groups (ESGs) may be disposed one atop the other (sharing vertical bitlines), and may constitute a single Physical Sector (PSec). There may be a number (such as tens of, such as 32) of Physical Sectors (PSecs) disposed one atop the other. The total number of Erase Sector Groups (ESGs) would thus be the number of ESGs per PSec (such as 32) times the number of PSecs (such as 32). In this example, there would be 1024 Erase Sector Groups (ESGs).

A Physical Sector (PSec) is a group of memory cells that share the same WLs and same bit lines. A Physical Sector (PSec) may comprise many more wordlines than an Erase Sector Group (ESG), since there are many ESGs in the PSec. A group of wordlines of a given PSec may be separated from another group of wordlines for another PSec by a select area comprising logic circuitry. When an address is asserted, only one given PSec may be active, and all others may be inactive.

Generally, the number of wordlines (WLs) in each of the Physical Sectors (PSecs) may be made to be the same as one another, to maintain the memory cells in the same physical “environment”. The number of wordlines (WLs) is typically a binary number, such as 1024 or 2048. This differs, for example, from technologies which may have different numbers of wordlines in different physical sectors of a given memory array. And, since the Physical Sectors (PSecs) are disposed one atop the other, they share the same bitlines (or sets of bitlines).

A Physical Page, also referred to as a “slice”, is generally a binary number (such as 32) of bitlines, and comprises vertically aligned segments of the Physical Sectors (PSecs), as well as corresponding vertically-aligned segments of the Erase Sector Groups (ESGs). Stated another way, a Physical Page (slice) comprises a column of many Erase Sectors (ESecs) which are disposed one above the other.

Multi-Level Programming

An NVM cell's threshold voltage level is usually correlated to the amount of charge stored in a charge storage region of the cell. Different threshold voltage ranges are associated with different states or program levels of an NVM cell.

An NVM memory cell may be programmed to different states, or program levels, determined by the threshold voltage (Vt) of the cell. In early NVM memory cells, there were generally only two program levels (or states), which represented binary “0” and binary “1” (or “erase and “program”) and this is referred to as “single level programming” (SLC). Generally, the program level is determined by the threshold voltage created by electrons (or holes) stored in the floating gate (of an FG cell) or in the charge-trapping medium (such as nitride layer, in NROM). For example, a binary “0” may have been represented by a threshold voltage (Vt) less than 4.0 volts, and a binary “1” may have been represented by a threshold voltage greater than 4.0 volts.

In modern NVM memory cells, there may be more than two program levels—for example, four program levels are possible, representing for example, binary “00” (zero), binary “01” (one), binary “10” (two) and binary “11” (three). This (having more than two program levels) is referred to as “multi-level programming” (MLC), and exemplary threshold voltages representing four program levels might be, for example:
the center value for “11” equals approximately 4.0 volts
the center value for “01” equals approximately 4.4 volts
the center value for “00” equals approximately 4.8 volts
the center value for “10” equals approximately 5.4 volts
   Thus, it is evident that multi-level programming is much more “sensitive” than single level programming and, when reading the contents of a memory cell, small changes or differences in measured voltage can lead to erroneous results.

Generally, in order to determine the state (program level) of an NVM cell, the cell's threshold level (Vt) may be compared to that of a reference structure or cell whose threshold level is set, or otherwise known to be, at a voltage level associated with the specific state being tested for. Comparing the threshold voltage of an NVM cell to that of a reference cell is often accomplished using a sense amplifier or similar circuit. Various techniques for comparing an NVM cell's threshold voltage against those of one or more reference cells or structures, in order to determine the NVM cell's state, are well known.

When reading an NVM cell, to determine whether it is at a particular state, the cell's threshold voltage may be compared against that of a reference cell having a reference threshold voltage defined as a “read” level for the specific state. A “read” level is usually set lower than a program verify (PV) level and higher than the erase verify (EV) level in order to compensate for voltage drifts which may occur during operation.

In a “binary” or single level cell (SLC) capable of storing only one bit of information (a logic 1 or a logic 0), only a single read verify (RV) voltage is required, and it may be between the erase verify (EV) and program verify (PV) voltages for the cell.

“Read” is generally done by measuring the Vt of a cell (or half-cell), and associating the measured Vt with a program level (such as “0” or “1”). Although the Vt's of the cells are measured on an individual basis, it is generally necessary to determine a distribution of Vt's for many cells in order to associate the measured Vt of a given cell with a program level, with confidence. For example—if only one cell were to be read, and its threshold voltage were to be found to be at or very near the Read Verify (RV) voltage between two program levels, it may be difficult to say, with certainty, at which of two program levels the single cell was programmed, since its threshold voltage may have moved slightly upward or slightly downward since it was programmed. This is a benefit of reading bits one block at a time—to obtain a statistically meaningful sample of Vt's across a number of cells.

FIG. 5A is a diagram illustrating two states of a “binary” or single level cell (SLC) capable of storing one bit of information per cell (or per charge trapping area with an NROM cell), and utilizes only one read verify threshold (RV). Generally, the two states are erased (represented by “1”) and programmed (represented by “0”). The horizontal axis is threshold voltage (Vt), increasing from left to right.

Three voltage levels are illustrated in FIG. 5A, these are EV (erase verify), RV (read verify) and PV (program verify). As illustrated, EV is less than RV which is less than PV. A high Vt may represent a program state of binary “0”, and a low Vt may represent an erase state of binary “1”. The binary designations are arbitrary, and may be reversed (high Vt=“1”, low Vt=“0”).

FIG. 5A is generalized, and is applicable to a typical floating gate NVM memory cell or a given charge storage area of an NROM cell. The curves represent the threshold voltages (Vts) for a number of cells at the given program level. Typically, there is a distribution, or spread, about a nominal (or average, or center) value. For example,
the center value for “1” equals approximately 3.5 volts
the center value for “0” equals approximately 6.0 volts
EV equals approximately 4.0 volts
RV equals approximately 4.5 volts
PV equals approximately 5.5 volts

FIG. 5B illustrates a situation wherein there are four possible MLC program levels (or states) 11, 01, 00, 10 for each memory cell (or, in the case of NROM, for each storage area of the memory cell). As illustrated, the program level 11 has the lowest Vt, the program level 01 has a higher Vt, the program level 00 has a yet higher Vt, and the program level 10 has a yet higher Vt. The program level 11 may be erase (ERS), which for purposes of this discussion is considered to be a program level, although it is not generally regarded as such.

There are a number of memory cells (or storage areas NROM cells) being programmed, erased and read. In a given array, or on a given memory chip, there may be many millions of memory cells. Programming may typically be performed in blocks, of thousands of memory cells. The different blocks of memory cells are typically located at different logical positions within the array, and at different physical positions on the chip. During (or before) programming, a checksum indicative of the number of cells programmed to each level may be stored, in the block, in the array, on the chip, or external to the chip.

At each program level (and this is also true for the SLC cell of FIG. 5A), there is typically a distribution of threshold voltages, within a range (a statistical spread). In other words, for a given program level, the threshold voltage is not likely to be exactly a unique, precise voltage for all of the memory cells being programmed to that level. Initially, in the act of programming the cell, the voltage may be off a bit, for example as a result of the state of neighboring cells (or the other charge storage area in the same NROM cell), or, as a result of previous program or erase operations on the same cell, or neighboring cells, or, as a result of a variety of other factors. And, after programming, the threshold voltage of a cell may change, as a result of programming neighboring cells (or the other charge storage area in the same NROM cell), or a variety of other factors.

Therefore, the threshold voltage (Vt) for a given program level may be more than average in some cells, in others it may be less than average. Nevertheless, in a properly functioning group of cells (such as a block, or an array), there should be a clear distribution of four distinct program levels, such as illustrated. And, the distributions of Vt for each of the program levels should be separated enough from one another so that read positions (RV voltage levels) can be established between adjacent distributions of threshold voltages, such as the following:
01 is between EV and PV01, or higher than the highest expected Vt for a cell at state “11” and lower than the lowest expected Vt for a cell at state “01”;
RV00 is between PV01 and PV00, or higher than the highest expected Vt for a cell at state “01” and lower than the lowest expected Vt for a cell at state “00”; and
10 is between PV00 and PV10, or higher than the highest expected Vt for a cell at state “00” and lower than the lowest expected Vt for a cell at state “10”.

For example,
the center value for “11” equals approximately 4.0 volts
the center value for “01” equals approximately 4.4 volts
the center value for “00” equals approximately 4.8 volts
the center value for “10” equals approximately 5.4 volts
EV equals approximately 4.0 volts
RV01 equals approximately 4.4 volts
PV01 equals approximately 4.8 volts
RV00 equals approximately 5.4 volts
PV00 equals approximately 5.6 volts
RV10 equals approximately 6.0 volts
PV10 equals approximately 6.3 volts

It should be noted that, although the distributions (such as 01) are shown entirely above (to the right of) their respective Program Verify (PV) values (such as PV01), typically soon after programming some cells may in a distribution may experience conditions (generally referred to as “disturb”) causing them to lose charge, and the distribution may be shifted slightly to the left. In FIG. 5B, PV10 is shown slightly within the left side of the “10” distribution to illustrate this point. Nevertheless, the “10” distribution is still all above RV10, and a valid read may be performed.

On the Use of Reference Cells

Non-volatile memory (NVM) cells may have data bits stored therein that may be read, such as by means of a sense amplifier (SA). When reading a memory cell, a current flowing into the drain or out of the source may be measured, in order to determine the Vt of the charge storage area above the source (or, in the case of a floating gate memory cell, the Vt of the floating gate), and a voltage may be ascertained which corresponds to a program level.

Many NVM arrays employ a “reference cell” as the basis for comparing the output of an “array cell” for a read operation. Both of these cells—the reference cell and the array cell—are memory cells, such as flash cells, and may be substantially identical with one another, although they may be located in different portions of the overall memory array (and, of course, on the same integrated circuit (IC) chip). The use of a reference cell may help compensate for changes in the overall array, such as due to voltage variations and temperature, and ensure a fairly stable reference for read operations.

Reference cells are memory cells that are programmed to one or more predetermined levels related to reading the contents (program level, data bits stored in) of the array cells. See, for example, U.S. Pat. No. 7,123,532 (Saifun, 2006) and U.S. Pat. No. 6,954,393 (Saifun, 2005).

Using reference cells to determine the program level of an array cell being read is somewhat analogous to “color matching”. For example, when a dentist is trying to determine a patient's tooth color, for manufacturing a prosthetic (false tooth), he may hold a card with reference colors (generally, all slightly different shades of white) up against the patient's tooth, comparing the reference colors to the patient's tooth color, looking for the best match. When holding a color sample against the patient's tooth, the dentist may determine that the tooth is either lighter than or darker than the color sample.

In the context of reading using reference cells, usually a value for Vt obtained from an array cell being read is compared against a “known” value from a reference cell and, using the sense amplifier (SA), it is determined whether the value read from the array cell is greater than the value retrieved from the reference cell. It is generally very important that the paths leading from the sense amps to the array cells are “matched” with the paths to the reference cells, and that they are operated in the same manner (for example, using the same drain drivers and Vds to read reference cells as are used to read the array cells).

Determining that Shifting RV is Necessary

Prior to or during the programming of a set of cells in an NVM array, the number of cells to be programmed to each of one or more logical or program states associated with the set of cells may be counted, and may be stored, for example, in a check sum table. The number of cells to be programmed to, up to and/or below each logical or program state may be counted and/or stored in a table which is either on the same array as the set of NVM cells or in memory on the same chip as the NVM array.

Upon the reading of the set of programmed cells, the number of cells found to be at a given logical or program state may be compared against either corresponding values stored during programming (such as the number of cells programmed to a given state) or against a value derived from the values stored during programming (such as the number of cells programmed at or above the given state, minus the number of cells programmed to or above an adjacent higher logical state).

If there is a discrepancy between the number of cells read at a given state and an expected number based on the values determined/counted/stored during programming, a Read Verify reference threshold value associated with the given program state may be adjusted upward or downward to compensate for the detected error. The read verify level of an adjacent logical state may also be moved upward or downward in order to compensate for detected read errors at a given state.

For example, if the number of cells found (read) in a given program state is below an expected value, either the Read Verify reference voltage associated with that given state may be reduced, or if there is found that the number of cells read above the given state exceeds an expected number, the Read Verify reference associated with a logical state higher and adjacent to the given state may be raised. Conversely, if the number of cells found. (for example, read) in a given program state is above expectations, either the Read Verify reference voltage associated with that given state may be increased, or if there is found that the number of cells read above the given state is below an expected number, the Read Verify reference associated with a logical state higher and adjacent to the given state may be lowered. Thus, Read Verify reference voltages for a set of cells may be selected such that the number of cells found/read in each of the states associated with the set may be substantially equal to a number either read from or derived from the values counted during programming of the set of cells, which values may have been stored in a check sum table.

The check sum table may reside on the same chip as the set of NVM cells, and a controller may be adapted to perform the above mentioned error detection and Read Verify reference value adjustments. The check sum table may either be stored in the same NVM array as the set of NVM cells, or on some other memory cells residing on the same chip as the NVM array, for example in a register or buffer used by the controller during programming and/or reading. Specialized error coding and detection circuits may be included with a controller on the same chip and the NVM array to be operated.

During the reading of the cells from the programmed set of cells, either the controller or some other error detection circuit may compare the number of cells counted in each program state during reading with the corresponding check sum values stored during or prior to programming. For example, if the number of cells found in a given program state exceed the value derived from the check sum values, the read verify (RV) threshold value associated with that given program state may be raised or the Read Verify reference level associated with the adjacent higher state may be lowered. Conversely, if the number of cells found in a given program state is below the expected number, either the read verify threshold value associated with the given program state may be lowered, or the read verify threshold value associated with the next higher adjacent state may be raised.

If the number of cells found (read) in a given program state is below an expected value, either the Read Verify reference voltage associated with that given state may be reduced, or if there is found that the number of cells read above the given state exceeds an expected number, the Read Verify reference associated with a logical state higher and adjacent to the given state may be raised. Conversely, if the number of cells found (for example, read) in a given program state is above expectations, either the Read Verify reference voltage associated with that given state may be increased, or if there is found that the number of cells read above the given state is below an expected number, the Read Verify reference associated with a logical state higher and adjacent to the given state may be lowered.

Thus, Read Verify reference voltages for a set of cells may be selected such that the number of cells found/read in each of the states associated with the set may be substantially equal to a number either read from or derived from the values counted during programming of the set of cells, which values may have been stored in a check sum table.

The steps described hereinabove may be repeated as part of an iterative process until the number of cells read in each program state substantially corresponds to the number of cells expected in each state based on data recorded during programming. The process may start with the checking of cells programmed to the highest logical state, or cells programmed to several different states may be checked in parallel.

Generally, when reading memory cells, the correct read verify (RV) voltage should be such that all of the cells programmed to a Vt higher than the RV voltage (or simply “RV”) should actually have a Vt that is higher than RV. For example, with reference to FIG. 5A, all of the cells programmed to “0” should have a threshold voltage higher than RV. And, for example, with reference to FIG. 5B,
all of the cells programmed to 01, 00 and 10 (all three non-erase states) should have a threshold voltage higher than RV01,
all of the cells programmed to 00 and 10 (the two higher of the three non-erase states) should have a threshold voltage higher than RV00, and
all of the cells programmed to 10 (the highest of the non-erase states) should have a threshold voltage higher than RV10.
And, by simply subtracting out the number of cells having a threshold voltage higher than RV01 from the entire population of cells, the number of cells programmed to 11 (defined as “erased”) can readily be determined.

Using error detection (ED) techniques, the number of cells programmed at each program level is known (it may be counted before or during programming). For example, if a given number (“X”) of cells (or storage areas of NROM cells) are known to have been programmed to 00 or 10, during read, there should be “X” cells with Vt greater than RV00. If there is a discrepancy (a different number of cells appear to have been programmed to a given level than are known to have been programmed at that level), various techniques, such as “moving read reference” may be used to correct the problem. (See, for example, U.S. Pat. No. 6,992,932.)

Commonly-owned patents disclose structure and operation of NROM and related ONO memory cells. Some examples may be found in commonly-owned U.S. Pat. Nos. 5,768,192 and 6,011,725, 6,649,972 and 6,552,387.

Commonly-owned patents disclose architectural aspects of an NROM and related ONO array, (some of which have application to other types of NVM array) such as segmentation of the array to handle disruption in its operation, and symmetric architecture and non-symmetric architecture for specific products, as well as the use of NROM and other NVM array(s) related to a virtual ground array. Some examples may be found in commonly-owned U.S. Pat. Nos. 5,963,465, 6,285,574 and 6,633,496.

Commonly-owned patents also disclose additional aspects at the architecture level, including peripheral circuits that may be used to control an NROM array or the like. Some examples may be found in commonly-owned U.S. Pat. Nos. 6,233,180, and 6,448,750.

Commonly-owned patents also disclose several methods of operation of NROM and similar arrays, such as algorithms related to programming, erasing, and/or reading such arrays. Some examples may be found in commonly-owned U.S. Pat. Nos. 6,215,148, 6,292,394 and 6,477,084.

Commonly-owned patents also disclose manufacturing processes, such as the process of forming a thin nitride layer that traps hot electrons as they are injected into the nitride layer. Some examples may be found in commonly-owned U.S. Pat. Nos. 5,966,603, 6,030,871, 6,133,095 and 6,583,007.

Commonly-owned patents also disclose algorithms and methods of operation for each segment or technological application, such as: fast programming methodologies in all flash memory segments, with particular focus on the data flash segment, smart programming algorithms in the code flash and EEPROM segments, and a single device containing a combination of data flash, code flash and/or EEPROM. Some examples may be found in commonly-owned U.S. Pat. Nos. 6,954,393 and 6,967,896.

Where applicable, descriptions involving NROM are intended specifically to include related oxide-nitride technologies, including SONOS (Silicon-Oxide-Nitride-Oxide-Silicon), MNOs (Metal-Nitride-Oxide-Silicon), MONOS (Metal-Oxide-Nitride-Oxide-Silicon) and the like used for NVM devices. Further description of NVM and related technologies may be found at “Non Volatile Memory Technology”, Vol. 1 & 2 (2005), Vol. 3 (2006) and Vol. 4 (2007), published by Saifun Semiconductor; “Microchip Fabrication”, by Peter Van Zant, 5^{th} Edition 2004; “Application-Specific Integrated Circuits” by Michael John Sebastian Smith, 1997; “Semiconductor and Electronic Devices”, by Adir Bar-Lev, 2^{nd} Edition, 1999; “Digital Integrated Circuits” by Jan M. Rabaey, Anantha Chandrakasan and Borivoje Nikolic, 2^{nd} Edition, 2002 and materials presented at and through http://siliconnexus.com, “Design Considerations in Scaled SONOS Nonvolatile Memory Devices” found at: http://klabs.org/richcontent/MemoryContent/nvmt_symp/nvmts_{—}2000/presentations/bu_white_sonos_lehigh_univ.pdf, “SONOS Nonvolatile Semiconductor Memories for Space and Military Applications” found at: http://klabs.org/richcontent/MemoryContent/nvmt_symp/nvmts_{—}2000/papers/adams_d.pdf, “Philips Research—Technologies—Embedded Nonvolatile Memories” found at: http://www.research.philips.com/technologies/ics/nvmemories/index.html, and “Semiconductor Memory: Non-Volatile Memory (NV)” found at: http://www.ece.nus.edu.sg/stfpage/elezhucx/myweb/NVM.pdf, all of which are incorporated by reference herein in their entirety.

Glossary

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).

When glossary terms (such as abbreviations) are used in the description, no distinction should be made between the use of capital (uppercase) and lowercase letters. For example “ABC”, “abc” and “Abc”, or any other combination of upper and lower case letters with these 3 letters in the same order, should be considered to have the same meaning as one another, unless indicated or explicitly stated to be otherwise. The same commonality generally applies to glossary terms (such as abbreviations) which include subscripts, which may appear with or without subscripts, such as “X_{yz}” and “Xyz”. Additionally, plurals of glossary terms may or may not include an apostrophe before the final “s”—for example, ABCs or ABC's.
bit The word “bit” is a shortening of the words “binary digit.” A bit refers to a digit in the binary numeral system (base 2). A given bit is either a binary “1” or “0”. For example, the number 1001011 is 7 bits long. The unit is sometimes abbreviated to “b”. Terms for large quantities of bits can be formed using the standard range of prefixes, such as kilobit (Kbit), megabit (Mbit) and gigabit (Gbit). A typical unit of 8 bits is called a Byte, and the basic unit for 128 Bytes to 16K Bytes is treated as a “page”. That is the “mathematical” definition of “bit”. In some cases, the actual (physical) left and right charge storage areas of a NROM cell are conveniently referred to as the left “bit” and the right “bit”, even though they may store more than one binary bit (with MLC, each storage area can store at least two binary bits). The intended meaning of “bit” (mathematical or physical) should be apparent from the context in which it is used.
BL short for bit line. The bit line is a conductor connected to the drain (or source) of a memory cell transistor.
byte A byte is commonly used as a unit of storage measurement in computers, regardless of the type of data being stored. It is also one of the basic integral data types in many programming languages. A byte is a contiguous sequence of a fixed number of binary bits. In recent years, the use of a byte to mean 8 bits is nearly ubiquitous. The unit is sometimes abbreviated to “B”. Terms for large quantities of Bytes can be formed using the standard range of prefixes, for example, kilobyte (KB), megabyte (MB) and gigabyte (GB).
disturb When applying a pulse to a specific bit by raising WL and/or BL voltages, neighboring bits located on the same WL and/or same BL might suffer from Vt shift that cause margin loss. The shift is called “disturb”. Disturbs are a fault type where the content of a cell is unintentionally altered when operating on another cell. These faults have similar characteristics to coupling faults, however, they have special neighborhood requirements.

Disturb faults are generally caused by the presence of high/intermediate electric field stress on an insulating layer within the core memory cell. This electric field results in leakage current caused by such physical mechanisms as FN-tunneling, punchthrough, or channel hot electron injection. Whether a given mechanism is responsible for a particular disturb is a function of the operating conditions and the state of the investigated cell.

The IEEE Standard Definition and Characterization of Floating Gate Semiconductor Arrays disturb faults can be divided into the following:

Word-line erase disturb (WED): Exists when a cell under program (selected cell) causes another programmed cell (unselected cell), sharing the same wordline, to be erased.

Word-line program disturb (WPD): Exists when a cell under program (selected cell) causes another unprogrammed cell (unselected cell), sharing the same wordline, to be programmed.

Bit-line erase disturb (BED): Exists when a cell under program (selected cell) causes another programmed cell (unselected cell), sharing the same bit-line, to be erased.

Bit-line program disturb (BPD): Exists when a cell under program (selected cell) causes another unprogrammed cell (unselected cell), sharing the same bitline, to be programmed.

Read disturb (RD): During read operation, the bias conditions are the same as programming conditions (except for lower voltage magnitudes) and can result in the injection of electrons from drain to gate, thus programming the selected cell. This known as soft program.
ED bits as used herein, ED bits are numbers which may be calculated for and stored along with data being programmed (stored), which are indicative of the number of cells (or half-cells) at any given program level. For example, 512 cells (or half cells) at program level “10”. During a subsequent read operation, the ED bits may be retrieved along with the data which was stored, the number of cells at the given program levels are counted, and these counts are compared with the ED bits. If there is a mismatch, this indicates a read error, and an error correction scheme such as “moving read reference” can be implemented. See moving read reference.
erase a method to erase data on a large set of bits in the array, such as by applying a voltage scheme that inject holes or remove electrons in the bit set. This method causes all bits to reach a low Vt level. See program and read.
FET short for field effect transistor. The FET is a transistor that relies on an electric field to control the shape and hence the conductivity of a “channel” in a semiconductor material. FETs are sometimes used as voltage-controlled resistors. The terminals of FETs are called gate (G), drain (D) and source (S).
FG short for floating gate. The floating-gate transistor is a kind of transistor that is commonly used for non-volatile storage such as flash, EPROM and EEPROM memory. Floating-gate transistors are almost always floating-gate MOSFETs. Floating-gate MOSFETs are useful because of their ability to store an electrical charge for extended periods of time even without a connection to a power supply.
Flash memory Flash memory is a form of non-volatile memory (EEPROM) that can be electrically erased and reprogrammed. Flash memory architecture allows multiple memory locations to be erased or written in one programming operation. Two common types of flash memory are NOR and NAND flash. NOR and NAND flash get their names from the structure of the interconnections between memory cells. In NOR flash, cells are connected in parallel to the bit lines, allowing cells to be read and programmed individually. The parallel connection of cells resembles the parallel connection of transistors in a CMOS NOR gate. In NAND flash, cells are connected in series, resembling a NAND gate, and preventing cells from being read and programmed individually: the cells connected in series must be read in series.

Some systems will use a combination of NOR and NAND memories, where a smaller NOR memory is used as software ROM and a larger NAND memory is partitioned with a file system for use as a random access storage area. NAND is best suited to flash devices requiring high capacity data storage. This type of flash architecture combines higher storage space with faster erase, write, and read capabilities over the execute in place advantage of the NOR architecture. See NAND, NOR.
Gray Code The reflected binary code, also known as Gray code after Frank Gray, is a binary numeral system where two successive values differ in only one digit. The reflected binary code was originally designed to prevent spurious output from electromechanical switches. Today, Gray codes are widely used to facilitate error correction in digital communications such as digital terrestrial television and some cable TV systems. An example of a two-bit Gray Code is 00, 01, 11, 10. (Notice that in “natural” binary counting, the sequence would be 00, 01, 10, 11, and in the step from 01 to 10, two bits (digits) are changed.) Another example of a two-bit Gray code would be 11, 01, 00, 10.
MLC short for multi-level cell. In the context of a floating gate (FG) memory cell, MLC means that at least two bits of information can be stored in the memory cell. In the context of an NROM memory cell, MLC means that at least four bits of information can be stored in the memory cell—at least two bits in each of the two charge storage areas.
moving read reference as used herein, “moving read reference” refers to a technique, such as disclosed in U.S. Pat. No. 6,992,932 wherein reference voltages are determined to be used in reading cells programmed to a given program state. Generally, if an error is detected, such as by using error detection (ED) bits, the reference voltages may have to be adjusted until the error is resolved. See ED bits.
NAND NAND flash architecture memories are accessed much like block devices such as hard disks or memory cards. The pages are typically 512 or 2,048 or 4,096 bytes in size. Associated with each page are usually a few bytes (typically 12-16 bytes) that are used for storage of an error detection (ED) and correction checksum.

The pages are typically arranged in blocks, such as 32 pages of 512 bytes, 64 pages of 2,048 bytes, or 64 pages of 4,096 bytes. With NAND architecture, programming may be performed on a page basis, but erasure can only be performed on a block basis.

Most NAND devices are shipped from the factory with some bad blocks which are typically identified and marked according to a specified bad block marking strategy. The first physical block (block 0) is always guaranteed to be readable and free from errors. Hence, all vital pointers for partitioning and bad block management for the device are located inside this block (typically a pointer to the bad block tables). If the device is used for booting a system, this block may contain the master boot record.
nitride commonly used to refer to silicon nitride (chemical formula Si3N4). A dielectric material commonly used in integrated circuit manufacturing. Forms an excellent mask (barrier) against oxidation of silicon (Si). Nitride is commonly used as a hard mask or, in the case of an NVM memory cell having an ONO layer, as a charge-trapping material.
NOR Reading from NOR flash is similar to reading from random-access memory, provided the address and data bus are mapped correctly. Because of this, most microprocessors can use NOR flash memory as execute in place (XIP) memory, meaning that programs stored in NOR flash can be executed directly without the need to copy them into RAM. NOR flash chips lack intrinsic bad block management, so when a flash block is worn out, the software or device driver controlling the device must handle this, or the device will cease to work reliably.
NROM short for nitride(d) read only memory. Generally, a FET-type device having a charge trapping medium such as a nitride layer for storing charges (electrons and holes) in two discrete areas, near the source and drain diffusions, respectively.
NVM short for non-volatile memory. NVM is computer memory that can retain the stored information even when not powered. Examples of non-volatile memory include read-only memory, flash memory, most types of magnetic computer storage devices (for example hard disks, floppy disk drives, and magnetic tape), optical disc drives, and early computer storage methods such as paper tape and punch cards. Non-volatile memory is typically used for the task of secondary storage, or long-term persistent storage. The most widely used form of primary storage today is a volatile form of random access memory (RAM), meaning that when the computer is shut down, anything contained in RAM is lost. Unfortunately most forms of non-volatile memory have limitations which make it unsuitable for use as primary storage. Typically non-volatile memory either costs more or performs worse than volatile random access memory. (By analogy, the simplest form of an NVM memory cell is a simple light switch. Indeed, such a switch can be set to one of two (binary) positions, and “memorize” that position.) NVM includes floating gate (FG) devices and NROM devices, as well a devices using optical, magnetic and phase change properties of materials.
ONO short for oxide-nitride-oxide. ONO is used as a charge storage insulator consisting of a sandwich of thermally insulating oxide, and charge-trapping nitride.
page Generally, a grouping of memory cells can be termed a word, a grouping of words can be termed a page, and a grouping of pages can be termed a sector. Data may be accessed for reading and programming (or writing) by word or by page, while an entire sector is commonly accessed for erasing. Other definitions of “page” may be used, throughout the industry and in this patent application.
program a method to program a bit in an array, by applying a voltage scheme that injects electrons. This method causes an increase in the Vt of the bit that is being programmed. Alternatively, with “high Vt erase”, programming may be a lowering of the Vt of the memory cell. See erase and read. Program may sometimes, erroneously be referred to as “write”. See write.
read a method to read the digital data stored in the array. The read operation is usually performed in “blocks” of several cells. See erase and program.
sector a part of a memory array, usually larger than a page, which usually contains a few pages. A minimum erase might include a sector. For example:

Erase Sector (ESec, or ES): Group of cells that are erased by single erase command

Physical Sector (PSec, or PS): Group of ES connected by single grid of Word Lines (WL) and Bit Lines (BL), sharing same set of drivers.
SLC short for single level cell. In the context of a floating gate (FG) memory cell, SLC means that one bit of information can be stored in the memory cell. In the context of an NROM memory cell, SLC means that at least two bits of information can be stored in the memory cell.
slice a portion of a memory array, such as a group of bitlines, that are connected to one sense amplifier (sense amp, “SA”)
SONOS Si-Oxide-Nitride-Oxide-Si, another way to describe ONO with the Si underneath and the Poly gate on top.
word line or wordline, (WL). A conductor normally connected to the gate of a memory cell transistor. The wordline may serve as the gate electrode of several of the memory cells.

### BRIEF DESCRIPTION (SUMMARY)

Two or more erase sectors (blocks) may be disposed in a given physical sector of a memory array, and may share wordlines with each other. This can lead to a “gate disturb” problem. (The gates of the memory cells are typically connected with the wordlines.)

According to the disclosure, generally, when (after) erasing a target block, it can be determined whether a neighbor block needs to be refreshed by checking a sub-population of Vt distributions at a given program level. Various timings and strategies for performing the refresh operation are disclosed. The effects of word line disturb (gate disturb) may thereby be reduced.

According to an embodiment of the disclosure, a method of operating a non-volatile memory array comprising: providing two or more erase sectors in a given physical sector of the array, each erase sector comprising a plurality of memory cells, one of which erase sectors is a target block, and another at least one of the two or more erase sectors are neighbor blocks; erasing the target block; determining whether to refresh the contents of at least one of the neighbor blocks; and refreshing the contents of the at least one of the neighbor blocks.

The non-volatile memory may comprise floating gate devices or charge-trapping devices such as nitride read only memory.

At least one of the neighbor blocks may share a wordline with the target block.

Refreshing the contents of at the least one of the neighbor blocks may comprise: injecting electrons into storage areas of selected ones of the memory cells in the at least one of the two or more erase sectors that are neighbor blocks, thereby increasing the threshold voltages of the selected ones of the memory cells in the at least one of the two or more erase sectors that are neighbor blocks.

Determining whether to refresh the contents of at least one of the neighbor blocks may comprise: selecting a sub-population of a total number of cells in a given program state; and checking a threshold voltage for the sub-population of cells in the given program state. The sub-population may represent a small percentage, such as approximately 1%, of the total number of cells in the given program state.

At least two adjacent program states may be established, one of which may be an erase state, and the following strategies may be employed, either singly or in combination with one another, for checking whether refresh is needed:
A higher of the two adjacent program states may be programmed so that a threshold voltage of selected ones of the memory cells are above a program verify value for the higher of the two adjacent program states, and determining whether to refresh the contents of at least one of the neighbor blocks may comprise: checking the threshold voltages for a portion of the memory cells in the higher of the two adjacent program states; and observing whether the threshold voltages for the portion of the memory cells in the higher of the two adjacent program states has shifted below the program verify value. The portion of memory cells which is checked may comprise a statistically valid sub-population of the total memory cells at the higher of the two adjacent program states. The statistically valid sub-population may be less than 5% of the total memory cells.
A higher of the two adjacent program states may be programmed so that there is a gap between a distribution of threshold voltages for memory cells in the higher of the two adjacent program states, and determining whether to refresh the contents of at least one of the neighbor blocks comprises: checking the threshold voltages for a portion of the memory cells in the higher of the two adjacent program states; and observing whether the gap has been narrowed to a threshold.
A higher of the two adjacent program states may be programmed so that a threshold voltage of selected ones of the memory cells are above a read value for the higher of the two adjacent program states, and determining whether to refresh the contents of at least one of the neighbor blocks may comprise: checking the threshold voltages for a portion of the memory cells in the higher of the two adjacent program states; and observing whether the threshold voltages for the portion of the memory cells in the higher of the two adjacent program states has shifted close to the read value.

The contents of the at least one of the neighbor blocks may be refreshed after every nth erase operation on the target block.

When there are many neighbor blocks, the contents of a first portion of the at least one of the neighbor blocks may be refreshed after a given erase operation on the target block; and a second portion of the at least one of the neighbor blocks may be refreshed after a subsequent erase operation on the target block.

When there are multiple possible distributions of threshold levels, when checking for disturb, different distributions may be checked each time, rather than always checking for disturb at given distribution of threshold levels.

According to an embodiment of the disclosure, a method of operating a non-volatile memory array comprises: using a sub-population of cells in order to identify a necessity for a refresh operation on a larger population of cells.

According to an embodiment of the disclosure, a non-volatile memory array comprises: two or more erase sectors in a given physical sector of the array, each erase sector comprising a plurality of memory cells, one of which erase sectors is a target block, and another of which at least one of the erase sectors are neighbor blocks; and at least one of the neighbor blocks shares a wordline with the target block. The target block and the neighbor blocks may be in a same physical sector of the memory array.

The techniques disclosed herein may be applicable to most NVM devices including, but not limited to, charge-trapping devices such as NROM (sometimes referred to as Nitride Read Only Memory), SONOS (Semiconductor Oxide Nitride Oxide Semiconductor; Silicon-Oxide-Nitride-Oxide-Silicon), SANOS (Silicon-Aluminum Oxide-Nitride-Oxide-Silicon), MANOS (Metal-Aluminum Oxide-Nitride-Oxide-Silicon), and TANOS (Tantalum-Aluminum Oxide-Nitride-Oxide-Silicon), and also to Floating Gate (FG) devices.

### BRIEF DESCRIPTION OF THE DRAWING(S)

Reference will be made in detail to embodiments of the disclosure, examples of which may be illustrated in the accompanying drawing figures (FIGs). The figures are intended to be illustrative, not limiting. Although the disclosure is generally described in the context of these embodiments, it should be understood that it is not intended to limit the disclosure to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. In some cases, hidden lines may be drawn as dashed lines (this is conventional), but in other cases they may be drawn as solid lines.

If shading or cross-hatching is used, it is intended to be of use in distinguishing one element from another (such as a cross-hatched element from a neighboring un-shaded element). It should be understood that it is not intended to limit the disclosure due to shading or cross-hatching in the drawing figures.

Elements of the figures may (or may not) be numbered as follows. The most significant digits (hundreds) of the reference number correspond to the figure number. For example, elements of FIG. 1 are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. (An alternative to the “100's increment” may be a different increment, such as a “20's increment”, where elements 120, 122 and 124 are comparable to elements 100, 102 and 104, for example.) Throughout the figures, each of a plurality of elements 199 may be referred to individually as 199a, 199b, 199c, etc. Such relationships, if any, between similar elements in the same or different figures will become apparent throughout the specification, including, if applicable, in the claims and abstract.

FIG. 1 is a stylized cross-sectional view of a field effect transistor (FET), according to the prior art. To the left of the figure is a schematic symbol for the FET.

FIG. 2 is a stylized cross-sectional view of a floating gate memory cell, according to the prior art. To the left of the figure is a schematic symbol for the floating gate memory cell.

FIG. 3 is a stylized cross-sectional view of a two bit NROM memory cell of the prior art. To the left of the figure is a schematic symbol for the NROM memory cell.

FIG. 4A is a diagram of a memory cell array, according to the prior art.

FIG. 4B is a diagram of a memory cell array, according to the prior art.

FIG. 5A is a diagram illustrating threshold voltage distributions for a population of single level (SLC) memory cells, according to the prior art.

FIG. 5B is a diagram illustrating threshold voltage distributions for a population of multi-level (MLC) memory cells, according to the prior art.

FIG. 6A is a diagram illustrating two adjacent threshold voltage distributions for a population of memory cells, after programming, according to the disclosure.

FIG. 6B is a diagram illustrating the two threshold voltage distributions for the population of memory cell of FIG. 6A, after disturb, according to the disclosure.

FIG. 6C is a diagram illustrating the two threshold voltage distributions for the population of memory cell of FIG. 6B, after refresh, according to the disclosure, according to the disclosure.

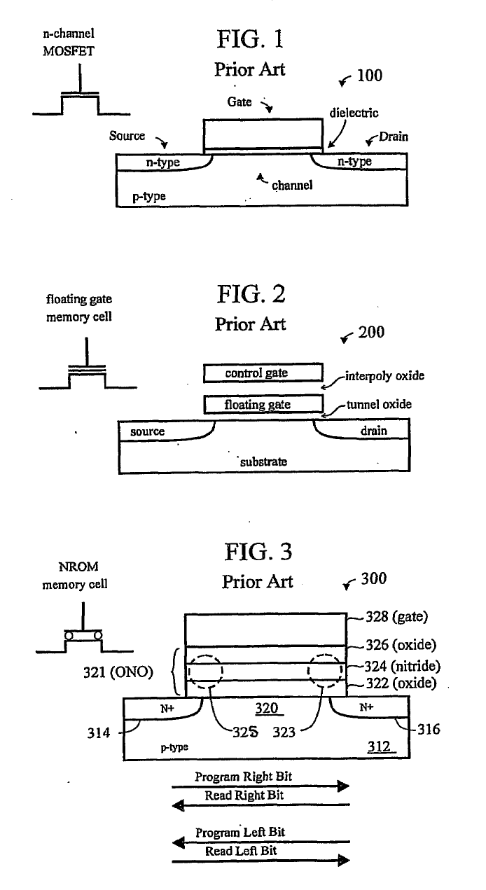

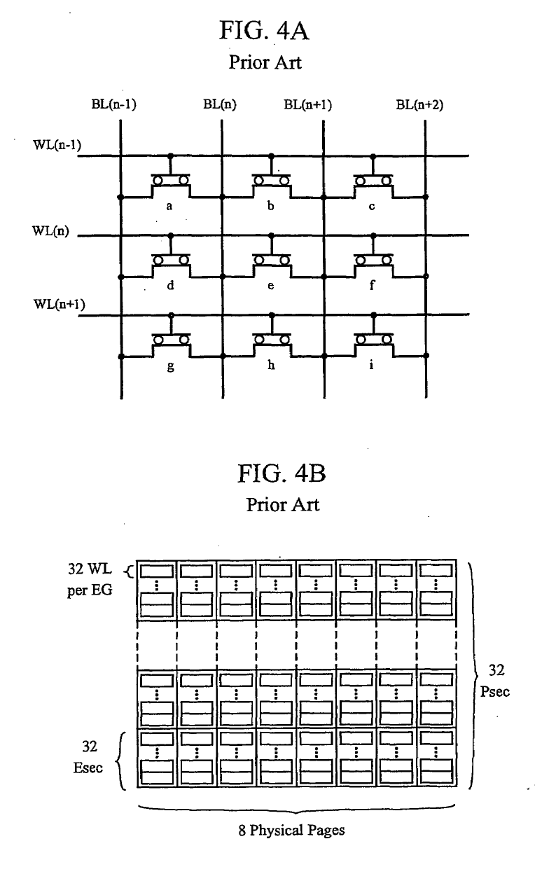

### DETAILED DESCRIPTION

In the following description, various aspects of techniques for operating NVM cells will be described. For the purpose of explanation, specific configurations and details are set forth in order to provide a thorough understanding of the techniques. However, it will also be apparent to one skilled in the art that the techniques may be practiced without specific details being presented herein. Furthermore, well-known features may be omitted or simplified in order not to obscure the description(s) of the techniques.

Throughout the descriptions set forth in this disclosure, lowercase numbers or letters may be used, instead of subscripts. For example Vg could be written V_{g}. Generally, lowercase is preferred to maintain uniform font size.) Regarding the use of subscripts (in the drawings, as well as throughout the text of this document), sometimes a character (letter or numeral) is written as a subscript—smaller, and lower than the character (typically a letter) preceding it, such as “Vₛ” (source voltage) or “H₂O” (water). For consistency of font size, such acronyms may be written in regular font, without subscripting, using uppercase and lowercase—for example “Vs” and “H2O”. Superscripts may be designated using a carat—for example, 2³⁰ may be written as “2̂30”. When powers of 10 are involved, the following notation may be used—for example, “2e13” means 2×10¹³.

Acronyms or abbreviations may be pluralized by adding an “s” at the end, either with or without an apostrophe—for example “Esecs” or “Esec's”, both being a plural form of the singular “Esec”.

Although various features of the disclosure may be described in the context of a single embodiment, the features may also be provided separately or in any suitable combination. Conversely, although the disclosure may be described herein in the context of separate embodiments for clarity, the disclosure may also be implemented in a single embodiment. Furthermore, it should be understood that the disclosure can be carried out or practiced in various ways, and that the disclosure can be implemented in embodiments other than the exemplary ones described herein below. The descriptions, examples, methods and materials presented in the description, as well as in the claims, should not be construed as limiting, but rather as illustrative.

Some portions of the detailed description that follows may be presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification discussions utilizing terms such as processing, computing, calculating, determining, or the like, refer to the action or processes of a computer or computing system, or similar electronic computing device, that manipulate or transform data represented as physical, such as electronic, quantities within the registers or memories of the computing system into other data similarly represented as physical quantities within the memories, registers or other such information storage, transmission or display devices of the computing system.

### Gate Disturb

Two or more Erase Sectors (ESecs, or “blocks”), each comprising a number of memory cells (which may, for example, be FG or NROM type memory cells), may be disposed in a given Physical Sector (PSec) of a memory array, with the gates of the memory cells in all of the neighboring blocks sharing the same wordline (WL) as one another. In such circumstances, when one (the “target”) block is erased, a different (“neighbor”) block located on (shares) the same word line (WL) as the target block may be subjected to a condition known as “gate disturb”, since the gates of its memory cells will be driven to a negative voltage. (During erase, the gate voltage may, for example, be −7 volts.) Gate disturb can lead to shifts in threshold voltage (Vt), resulting in reliability problems.

An overall goal of the present disclosure is to provide techniques for solving the problem of “gate disturb” (or “wordline disturb”). A simple solution would be to allocate only one erase block in each physical sector, but that would involve significant array overhead (each physical sector requires circuitry distinct from other physical sectors). The techniques disclosed herein enable (facilitate) allocating multiple (two or more) erase blocks in one physical sector, and in that way reduce array overheads.

The techniques disclosed herein generally involve refreshing the contents of a population of memory cells, such as the memory cells in a given erase block, as well as determining when refresh is necessary, and when to do it.

Generally, the disturb problem referred to here is exemplary of any kind of effect that degrades threshold voltage in memory cells. Typically, the degradation exhibits itself as a downward (towards zero) shift in threshold voltage.

For purposes of the descriptions set forth herein, “program” involves injecting electrons into the storage area(s) of memory cells, which increases their threshold voltage.

Generally, “refresh” involves reading the threshold voltages of one or more memory cells, for example at a given program level, determining if “refresh” is necessary (the threshold voltages have dropped), and providing programming pulses (re-programming) to increase the threshold voltages of the memory cells.

An “Erase block” (or simply “block”), which may also be referred to as an “erase sector” (ESec), is the smallest group of memory cells that can be erased together, from the user point of view, in the same user command. Recall from above that there may be several erase sectors (ESecs) in any given Physical Sector (PSec). Many erase sectors (ESecs) may share a common wordline (or wordlines).

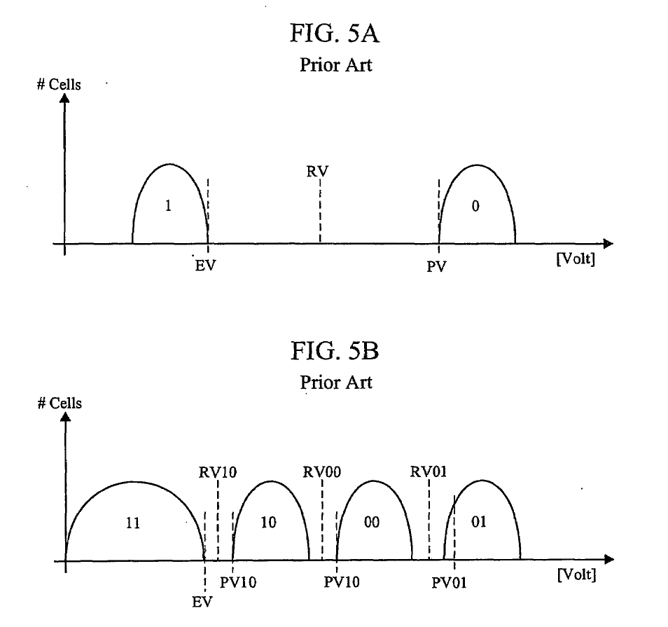

When a block is being erased, the wordlines (cell gates) of the block are set to a high negative voltage, such as −7 volts, the drains of the cells may be set to +5 volts, and the sources of the cells may be left floating. The purpose of erase is to reduce the Vt of the erased cells. See, for example, the “11” distribution in FIG. 5B.

Incident to erasing a given block (which may be referred to herein as a “target” block), memory cells from neighboring blocks which share the same wordlines as the target cells in the target block being erased may be disturbed. This phenomenon may be referred to as “gate disturb” (or “wordline disturb”). Generally, “disturb” will manifest itself as a reduction in Vt (charge loss) in the affected cells in the neighbor block.

Generally, to minimize (or inhibit) gate disturb, different voltages (such as a minus voltage on the drain) may be placed on the drain and source of cells of the neighbor block to minimize (or inhibit) the disturb. But the significant gate voltage on the wordline is nevertheless likely to cause gate disturb in neighboring blocks. Particularly, after repeated erasing of a target block, the neighbor block(s) are likely to suffer from charge loss (Vt shift), and may be disturbed in a significant way (such as loss of data).

One way to locate two or more Blocks on (in) the same Physical Sector is to locate on the same wordline (WL) cells that belong to different Blocks (Neighbor Blocks). In that case when one block is erased, a different block located on the same word line (WL) experiences a “gate disturb”, since it's WLs are driven to negative voltage. Cumulative (repeated) instances of this disturb can result in reliability problems. An example of a “worst case” scenario (from a disturb point of view) is that the user is programming and erasing one block, while the neighbor block is programmed only once.

Some of the technical problems solved may include:
1. Enabling locating two or more blocks on the same WL
2. Improving Gate Disturb as result of location of few blocks on the same WL.

One “solution” would be to put every block in a separate physical sector. Another solution would be to put different blocks, that belong to the same physical sector, in separate word lines. This way the “gate disturb” would be limited to one cycle, but the area penalty would be high.

Neighbor Block Refresh, Illustration

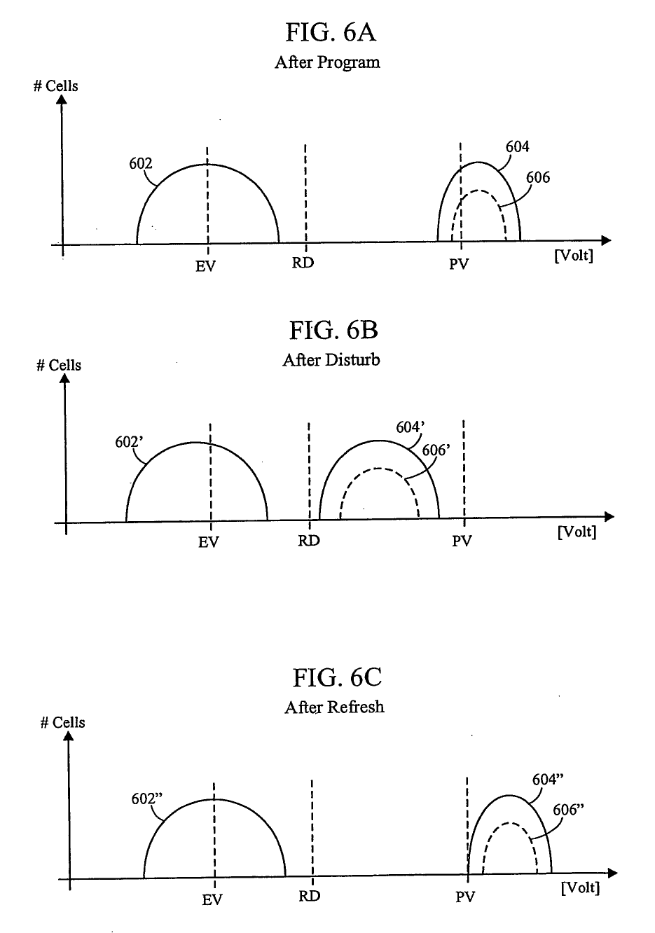

FIG. 6A illustrates two populations of memory cells. A first population 602 is representative, for example, of a total number of cells in the erase state, such as “11” in FIG. 5B. A second population 604 is representative, for example, of a total number of cells in a first program state, such as “10” in FIG. 5B. (For purposes of this example, the “erase” state may be considered to be one of several “program” states.)

The two program states shown in FIG. 6A may be considered to be two adjacent program states, such as “11” and “01” in FIG. 5B. (Rather than, for example, “01” and “10” in FIG. 5B.) The higher (to the right) of the two adjacent program states has been programmed, in a conventional manner, so that the threshold voltage of its memory cells are all above a program verify value.

The dashed line 606 represents a sampling, or sub-set of the second population of cells 604. For example, the sub-population 606 may be (may represent) a small percentage, such as approximately 1% (one percent) or less, of the total number of cells in the second population 604.

In FIG. 6A, the condition (Vt, status) of cells which have been programmed is illustrated after programming. For purposes of this discussion, these cells are representative of the cells in a given block which may be a “neighbor” of a “target” block (not shown) being erased. Generally, after programming, the cells are in a more or less “pristine” state. There is a distribution of cells in the distribution 602, more or less centered around an Erase Verify (EV) value, and there is a distribution of cells in the distribution 604 more or less above the Program Verify (PV) value. (Recall that almost immediately after programming, cells may lose some charge due to disturbing conditions.) All of the cells in the distribution 604 are above the Read Value (RD). And, there is a wide gap between the distribution 602 and the distribution 604.

As mentioned above, due to the fact that the cells in the given (illustrated) block may share wordlines with another block (not shown) being erased, both of the distributions 602 and 604 may be shifted, typically downwards (to the left, representing a loss of charge, or moving closer to the erase state.) The target block (not shown) being erased may very well be erased a number of times, each time exacerbating the downward shift of Vt's in the cells of the illustrated block. It should be understood that a number of other factors in blocks or portions of the overall memory array, other than in the aforementioned “target” block being erased, can cause degradation (downward shift) of Vt in the cells of the given (illustrated) block.

In FIG. 6B, the condition (Vt, status) of cells in the two distributions 602′ and 604′ are shown. The reference numerals are primed (′) to indicate that things are different in FIG. 6B than they were in FIG. 6A. Because of wordline disturb, or any other condition that may deplete charge from the storage regions of the memory cells, it can be noticed in FIG. 6B that the distribution 602′ (prime) has shifted slightly to the left, and that the distribution 604′ (prime) has shifted significantly to the left. (Generally, the distributions at higher program levels will shift more when disturbed than the distribution at erase level.)

Determining when to refresh can be based on checking the threshold voltages of the memory cells in the higher (604) of the two adjacent program states, and observing that at least a substantial portion of the memory cells in the higher (604) of the two adjacent program states (602 and 604) has shifted below the program verify PV value. In FIG. 6B, all of the cells in the program state 604′ have shifted below PV. The distribution 604′ is shown as having moved entirely to the left of its Program Verify (PV) value.

Also, there is now a very narrow gap between the distributions 602′ and 604′. Fortunately (or fortuitously), the Read Value (RD) can still be used, since all of the cells in the distribution 604′ are above RD, but it can be seen that the situation has become very tenuous, and with a little more disturb, and resulting downward shift of Vt, the cells in the distribution 604′ could become corrupted, requiring error correction techniques such as moving read reference to accurately read the cells that have shifted their Vt below RD.

According to an embodiment of the disclosure, generally, when erasing a target block, or immediately after erasing a target block, the cells of a neighbor block (illustrated in FIGS. 6A and 6B) may be checked to see if they need to be refreshed. The entire population of the block need not be checked, and the populations at all of the program levels (if MLC) need not necessarily be checked. It is generally sufficient, and statistically valid, to check a sub-population (606′) of one program level distribution (604′) to determine if a refresh operation is required and, if it is required, then all of the cells at the examined program level, as well as all of the cells at other program (as well as erase) levels can be refreshed.

The “need to be refreshed” may be based on statistical studies, and may be determined to be required when the gap between two adjacent distribution levels is degraded (narrowed) to a threshold, or when some of the cells in the distribution (or sub-population) being examined have slipped uncomfortably close to (such as within a fraction of a volt, such as within 0.1 volts of) the Read Value (RD), for example. When any of the parameters such as RD and PV which are designed into the system start to become compromised, generally all of which are constantly being monitored, this may signal a requirement to perform a refresh operation.

When the refresh operation is performed, it may be performed on an entire block, and will usually proceed on a cell-by-cell basis, involving reading the Vt of a cell and, if a cell's Vt is below PV, providing programming pulses to raise the Vt of the cell above PV. This is akin to a “normal” programming operation. (Although in “normal” programming, there may, for example, be an erase operation performed before programming, to “level things” out before programming. Here, in “refresh”, the Vt of the cell is already programmed, but degraded, and just needs a little “fixing”.)

The sub-population of cells being checked to determine whether refresh is required may be a small, representative portion of the overall population of the cells at a given program level. For example, less than 5%, less than 3%, approximately 1%, less than 1%, less than 0.5%. As will be understood by “a person of ordinary skill in the art”, choosing the size of the sub-population, and selecting which cells belong to the subpopulation is a statistics-based decision that may vary between products. Generally, the sub-population is selected to be an efficient size, and statistically-representative of the overall population.

After determining that a refresh operation is required, and after performing the refresh operation, the Vt distributions for the cells in the “disturbed” block should look substantially like they did after programming (FIG. 6A). This “after refresh” condition is shown in FIG. 6C, which is almost identical to FIG. 6A. A small difference being shown in FIG. 6C is that since the cells are freshly re-programmed (refreshed), there may not be any slippage (yet) of the Vt of the cells in distribution 604″ (double prime) below PV. The subpopulation of 604″ is labeled 606″ (double prime), and the cells in the distribution 602″ (double prime) are brought back up to their desired levels.

Implementation/Timing

The basic idea, described hereinabove, is to perform a refresh operation on a block of disturbed cells. The timing and strategy of the refresh operation may depends on (be adapted to) the application, for example:
1. after every erase operation on a given (target) block, routinely refresh one or more of the erased block's neighbor blocks, including:
   a. Refresh can be performed every time an erase operation is performed, or every nth (such as every one, every second, every third, every fourth and so forth) time that an erase operation is performed and/or
   b. In the case of many neighbor blocks which are presumed to have been disturbed, refresh can be performed on some of the neighbor blocks after one erase of the target block, on other of the neighbor blocks after a subsequent erase of the target block, and so forth.
2. After every one or more erase operation(s), read the presumed-to-be disturbed population of one or more neighbor blocks, entirely, or a subpopulation of the neighbor block. If a disturb is seen, refresh the entire neighbor block. Including:
   a. Check each neighbor block (entirely, or only a subpopulation of the block), and refresh only the neighbor block that has been disturbed.
   b. Check all of the neighbor blocks (entirely, or only a subpopulation of the blocks), until a disturb is discovered, then perform refresh on the disturbed block(s)
3. When checking for disturb, dynamically adjust the thresholds which are used to declare a “disturb”, such as how close a distribution is getting to RD, or the size of the gap between two adjacent distributions.
4. When checking for disturb, check different distributions (of multiple “MLC” distributions, or program states, or levels, for example as illustrated in FIG. 5B) each time, rather than always checking for disturb at given distribution (program state/level) of threshold levels.
5. any combination of the above (1.-4.)

Generally, the gate disturb results in reduction of the Vt of the memory cells. The Refresh operation is re-programming (or “touching up” the programming on) all the cells that have moved below a certain Vt level back to a higher Vt level. This occurs as an internal procedure. The user may not, and generally need not, be aware of the internal procedure taking place when an Erase command is issued.

Generally, the solution set forth in this disclosure is to refresh a neighbor block, during (such as following, or after) the erase operation performed on the target block.

Generally, an assumption may be made that one erase operation will not cause a dramatic disturb, but that an accumulation of erase operations will. Therefore the neighbor blocks may be checked when the erase operation is over (not after a few pulses)—in other words, following the erase operation.

Since programming (including refresh, which can be viewed as partial programming) can take place much more quickly than Erase, the entire operation (Erase+Refresh) may be completed within the time defined for the desired erase operation. In other words, the refresh procedures described herein, including checking whether refresh is necessary and performing it if it is, can be done substantially without slowing things down.

Some NVM products “break” the memory array to segments. Each segment may comprise a few Erase sectors. If it is feasible, from an application point of view, it would be desirable to refresh the array whenever possible to assure maximum reliability. However, more realistically, since user erase command execution time is limited by products spec, generally only the “most likely” to be disturbed population may be refreshed.

A specific population (sub-population) of cells may be used in order to identify the necessity of Refresh operation on larger populations of cells. Refresh involves first reading the contents of the cells (population or sub-population). When reading, any suitable read algorithm and/or technique may be used, as well as its improvements, such as the moving read reference technique. The read algorithm may improve the total algorithm in terms of performance, reliability or other parameters. In other words, for example, the moving read reference algorithm (such as the mechanism inherent therein of detecting a significant shift of a population of cells Vt) can help determining if refresh is needed.

The goal of performing the procedures described hereinabove is generally to reduce the effects of word line disturb (gate disturb). However, the procedures may be implemented to reduce any degradation of Vt's (population shift), whatever the cause may be. The techniques disclosed herein may also help in RAC (retention after cycling). The techniques disclosed herein can be provided as an option, to be enabled or disabled.

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions and sub-combinations.

What is claimed is:

1. A method of operating a non-volatile memory array comprising:
providing two or more erase sectors in a given physical sector of the array, each erase sector comprising a plurality of memory cells, one of which erase sectors is a target block, and another at least one of the two or more erase sectors are neighbor blocks;
erasing the target block;
determining whether to refresh the contents of at least one of the neighbor blocks; and
refreshing the contents of the at least one of the neighbor blocks.

2. The method of claim 1, wherein the non-volatile memory comprises floating gate devices.

3. The method of claim 1, wherein the non-volatile memory comprises charge-trapping devices.

4. The method of claim 3, wherein the charge-trapping devices comprise nitride read only memory.

5. The method of claim 1, wherein at least one of the neighbor blocks shares a wordline with the target block.

6. The method of claim 1, wherein refreshing the contents of at the least one of the neighbor blocks comprises:
injecting electrons into storage areas of selected ones of the memory cells in the at least one of the two or more erase sectors that are neighbor blocks, thereby increasing the threshold voltages of the selected ones of the memory cells in the at least one of the two or more erase sectors that are neighbor blocks.

7. The method of claim 1, wherein determining whether to refresh the contents of at least one of the neighbor blocks comprises:
selecting a sub-population of a total number of cells in a given program state; and
checking a threshold voltage for the sub-population of cells in the given program state.

8. The method of claim 7, wherein:
the sub-population represents a small percentage of the total number of cells in the given program state.

9. The method of claim 8, wherein the small percentage is approximately 1%.

10. The method of claim 1, further comprising:
establishing at least two adjacent program states, one of which may be an erase state; and
programming a higher of the two adjacent program states so that a threshold voltage of selected ones of the memory cells are above a program verify value for the higher of the two adjacent program states;
wherein determining whether to refresh the contents of at least one of the neighbor blocks comprises:
checking the threshold voltages for a portion of memory cells in the higher of the two adjacent program states; and
observing whether the threshold voltages for the portion of the memory cells in the higher of the two adjacent program states has shifted below the program verify value.

11. The method of claim 10, wherein the portion of memory cells which is checked comprises a statistically valid sub-population of the total memory cells at the higher of the two adjacent program states.

12. The method of claim 11, wherein the statistically valid sub-population less than 5%, of the total memory cells.

13. The method of claim 1, further comprising:
establishing at least two adjacent program states, one of which may be an erase state; and
programming a higher of the two adjacent program states so that there is a gap between a distribution of threshold voltages for memory cells in the higher of the two adjacent program states;
wherein determining whether to refresh the contents of at least one of the neighbor blocks comprises:
checking the threshold voltages for a portion memory cells in the higher of the two adjacent program states; and
observing whether the gap has been narrowed to a threshold.

14. The method of claim 1, further comprising:
establishing at least two adjacent program states, one of which may be an erase state; and
programming a higher of the two adjacent program states so that a threshold voltage of selected ones of the memory cells are above a read value for the higher of the two adjacent program states;
wherein determining whether to refresh the contents of at least one of the neighbor blocks comprises:
checking the threshold voltages for a portion of memory cells in the higher of the two adjacent program states; and
observing whether the threshold voltages for the portion of the memory cells in the higher of the two adjacent program states has shifted close to the read value.

15. The method of claim 1, further comprising:
refreshing the contents of the at least one of the neighbor blocks after every nth erase operation on the target block.

16. The method of claim 1, wherein there are many neighbor blocks, and further comprising:
refreshing the contents of a first portion of the at least one of the neighbor blocks after a given erase operation on the target block; and
refreshing the contents of a second portion of the at least one of the neighbor blocks after a subsequent erase operation on the target block.

17. The method of claim 1, wherein there are multiple possible distributions of threshold levels, further comprising:
when checking for disturb, check different distributions each time, rather than always checking for disturb at given distribution of threshold levels.

18. A method of operating a non-volatile memory array comprising:
using a sub-population of cells in order to identify a necessity for a refresh operation on a larger population of cells.

19. A non-volatile memory array comprising:
two or more erase sectors in a given physical sector of the array, each erase sector comprising a plurality of memory cells, one of which erase sectors is a target block, and another at least one of the erase sectors are neighbor blocks; and
at least one of the neighbor blocks shares a wordline with the target block.

20. The non-volatile memory array of claim 19, wherein the target block and the neighbor blocks are in a same physical sector of the memory array.
